(19) United States
(12) Patent Application Publication
(10) Pub. No.: US 2014/0181602 A1
(43) Pub. Date: Jun. 26, 2014

(54) MODELING MEMORY ARRAYS FOR TEST PATTERN ANALYSIS

(71) Applicants: Vibhor Mittal, Austin, TX (US); Anirudh Kadiyala, Austin, TX (US)

(72) Inventors: Vibhor Mittal, Austin, TX (US); Anirudh Kadiyala, Austin, TX (US)

(73) Assignee: ADVANCED MICRO DEVICES, INC., Sunnyvale, CA (US)

(21) Appl. No.: 13/725,185

(22) Filed: Dec. 21, 2012

(51) Int. Cl. G11C 29/10

(52) U.S. Cl. CPC G11C 29/10
USPC 714/720

(57) ABSTRACT

A method includes receiving in a computing apparatus a model of an integrated circuit device including a memory array. The memory array is modeled as a plurality of device primitives. A test pattern analysis of the memory array is performed using the model in the computing apparatus. A system includes a memory array modeling unit and a test pattern analysis unit. The memory array modeling unit is operable to generate a model of an integrated circuit device including an memory array. The memory array is modeled as a plurality of device primitives. The test pattern analysis unit is operable to performing a test pattern analysis of the memory array using the model in the computing apparatus.

### BACKGROUND

The present subject matter relates generally to semiconductor device manufacturing and, more particularly, to modeling memory arrays for test pattern analysis.

The fabrication of complex integrated circuits involves the fabrication of a large number of transistor elements, which are used in logic circuits as switching devices. Generally, various process technologies are currently practiced for complex circuitry, such as microprocessors, storage chips, and the like. During the fabrication of complex integrated circuits, millions of transistors are formed on a substrate including a crystalline semiconductor layer. These devices form various logic and memory components of the circuit.

Various techniques are used to test the functionality of the completed circuits. One technique for characterizing integrated circuit devices is commonly referred to as scan testing. In a scan topology, the flip flops of a logic unit are placed into a serial chain using alternate test mode routing circuitry, resulting in a circuit resembling a serial shift register with as many stages as the number of flip flops. Test patterns are shifted into the flip flops to test the logic circuitry of the device. After a test pattern is loaded into the flip flops, the response of the logic circuitry is captured in one or more of the flip flops using one or more scan clock pulses. After the results are captured, a new test pattern may be loaded into the flip flops for another test iteration while shifting out responses for the previous test pattern.

Automated test pattern generation (ATPG) techniques involve modeling the components in the device as a plurality of primitive devices, as opposed to individual transistors. A series of test patterns are generated to test the functionality of the primitive devices. Fault grading simulation is used with a series of test patterns that have been generated by ATPG software to determine the efficacy of the fault coverage.

Typically, ATPG and fault grading simulation techniques, collectively referred to as test pattern analysis, do not cover memory arrays in an integrated circuit device, but rather only the discrete memory components, such as flip-flops. Memory arrays are typically covered my memory built-in self test (MBIST) circuitry. In an MBIST test, the MBIST logic cycles through the array to test that the patterns written into the array are correctly read out of the array. MBIST circuitry is not capable of identifying all faults in an array. MBIST is not able to generate a coverage metric identifying the percentage of potential faults covered. MBIST assumes an ideal condition of covering 100% of faults. For example, MBIST is not capable of determining whether a pre-charge circuit or a keeper circuit of the memory macro has a silicon defect.

This section of this document is intended to introduce various aspects of art that may be related to various aspects of the present subject matter described and/or claimed below. This section provides background information to facilitate a better understanding of the various aspects of the present subject matter. It should be understood that the statements in this section of this document are to be read in this light, and not as admissions of prior art. The present subject matter is directed to overcoming, or at least reducing the effects of, one or more of the problems set forth above.

### BRIEF SUMMARY

The following presents a simplified summary of the present subject matter in order to provide a basic understanding of some aspects thereof. This summary is not an exhaustive overview of the present subject matter. It is not intended to identify key or critical elements of the subject matter or to delineate the scope of the subject matter. Its sole purpose is to present some concepts in a simplified form as a prelude to the more detailed description that is discussed later.

Some embodiments include a method that includes receiving in a computing apparatus a model of an integrated circuit device including a memory array. The memory array is modeled as a plurality of device primitives. A test pattern analysis of the memory array is performed using the model in the computing apparatus.

Some embodiments include a system including a memory array modeling unit and a test pattern analysis unit. The memory array modeling unit is operable to generate a model of an integrated circuit device including an memory array. The memory array is modeled as a plurality of device primitives. The test pattern analysis unit is operable to performing a test pattern analysis of the memory array using the model in the computing apparatus.

### BRIEF DESCRIPTION OF THE DRAWINGS

The present subject matter will hereafter be described with reference to the accompanying drawings, wherein like reference numerals denote like elements, and:

FIG. 1 is a simplified block diagram of a modeling computing apparatus for modeling the performance of semiconductor devices, according to some embodiments;

FIG. 2 is a diagram illustrating the operation of the modeling computing apparatus of FIG. 1, according to some embodiments;

FIGS. 3 and 4 are diagrams illustrating the modeling of memory arrays for ATPG analysis, according to some embodiments; and

FIGS. 5 and 6 are diagrams illustrating the modeling of memory arrays for fault grading analysis, according to some embodiments.

While the present subject matter is susceptible to various modifications and alternative forms, specific embodiments thereof have been shown by way of example in the drawings and are herein described in detail. It should be understood, however, that the description herein of specific embodiments is not intended to limit the subject matter to the particular forms disclosed, but on the contrary, the intention is to cover all modifications, equivalents, and alternatives falling within the spirit and scope of the present subject matter as defined by the appended claims.

### DETAILED DESCRIPTION

One or more specific embodiments of the present subject matter will be described below. It is specifically intended that the present subject matter not be limited to the embodiments and illustrations contained herein, but include modified forms of those embodiments including portions of the embodiments and combinations of elements of different embodiments as come within the scope of the following claims. It should be appreciated that in the development of any such actual implementation, as in any engineering or design project, numerous implementation-specific decisions must be made to achieve the developers' specific goals, such as compliance with system-related and business related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure. Nothing in this application is considered critical or essential to the present subject matter unless explicitly indicated as being “critical” or “essential.”

The present subject matter will now be described with reference to the attached figures. Various structures, systems and devices are schematically depicted in the drawings for purposes of explanation only and so as to not obscure the present subject matter with details that are well known to those skilled in the art. Nevertheless, the attached drawings are included to describe and explain illustrative examples of the present subject matter. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

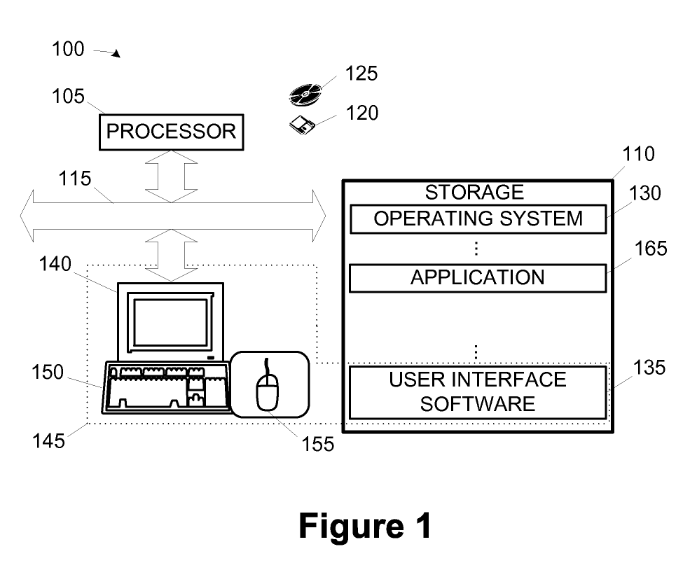

Referring now to the drawings wherein like reference numbers correspond to similar components throughout the several views and, specifically, referring to FIG. 1, the present subject matter shall be described in the context of an illustrative modeling computing apparatus 100 for performing test pattern analysis for semiconductor devices. For example the modeling computing apparatus 100 may perform an ATPG analysis to generate test patterns for a particular device, or the modeling computing apparatus 100 may perform fault grading simulation to determine how well a particular set of ATPG patterns is capable of identifying faults in the device. Fault grading rates testability by relating the number of fabrication defects that can in fact be detected with a test vector set under consideration to the total number of conceivable faults. Fault grading may be used for refining both the test circuitry and the ATPG test patterns iteratively, until a satisfactory fault coverage is obtained.

The computing apparatus 100 includes a processor 105 communicating with storage 110 over a bus system 115. The storage 110 may include a hard disk and/or random access memory (“RAM”) and/or removable storage, such as a magnetic disk 120 or an optical disk 125. The storage 110 is also encoded with an operating system 130, user interface software 135, and a test pattern analysis application 165. The user interface software 135, in conjunction with a display 140, implements a user interface 145. The user interface 145 may include peripheral I/O devices such as a keypad or keyboard 150, mouse 155, etc. The processor 105 runs under the control of the operating system 130, which may be practically any operating system known in the art. The application 165 is invoked by the operating system 130 upon power up, reset, user interaction, etc., depending on the implementation of the operating system 130. The application 165, when invoked, performs a method of the present subject matter. The user may invoke the application 165 in conventional fashion through the user interface 145. Note that although a stand-alone system is illustrated, there is no need for the data to reside on the same computing apparatus 100 as the application 165 by which it is processed. Some embodiments of the present subject matter may therefore be implemented on a distributed computing system with distributed storage and/or processing capabilities.

It is contemplated that, in some embodiments, the application 165 may be executed by the computing apparatus 100 to implement one or more device models and simulation units described hereinafter to model the performance of an integrated circuit device. Data for the simulation may be stored on a computer readable storage device (e.g., storage 110, disks 120, 125, solid state storage, and the like).

Portions of the subject matter and corresponding detailed description are presented in terms of software, or algorithms and symbolic representations of operations on data bits within a computer memory. These descriptions and representations are the ones by which those of ordinary skill in the art effectively convey the substance of their work to others of ordinary skill in the art. An algorithm, as the term is used here, and as it is used generally, is conceived to be a self-consistent sequence of steps leading to a desired result. The steps are those requiring physical manipulations of physical quantities. Usually, though not necessarily, these quantities take the form of optical, electrical, or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise, or as is apparent from the discussion, terms such as “processing” or “computing” or “calculating” or “determining” or “displaying” or the like, refer to the action and processes of a computer system, or similar electronic computing device, that manipulates and transforms data represented as physical, electronic quantities within the computer system's registers and memories into other data similarly represented as physical quantities within the computer system memories or registers or other such information storage, transmission or display devices.

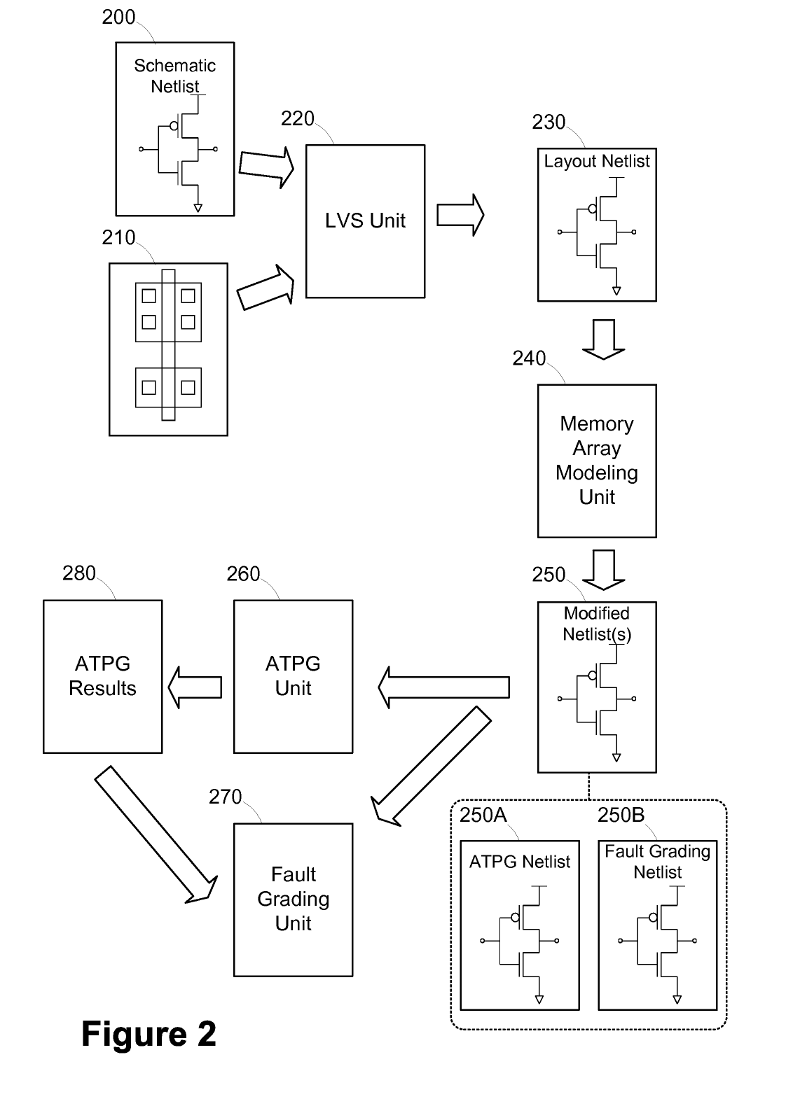

A general process flow for the computing apparatus 100 in implementing the simulation activities of the application 165 is shown in FIG. 2, according to some embodiments. Inputs to the application 165 include a schematic netlist 200 that includes base entries defining the discrete devices included in a semiconductor device and a layout file 210 that defines how the devices in the schematic netlist 200 are physically implemented in silicon. A layout versus schematic (LVS) unit 220 compares the schematic netlist 200 and the layout file 210 to determine whether the integrated circuit layout corresponds to the original schematic of the design. In general, LVS employs equivalence checking, which checks whether two circuits perform the exact same function without demanding exact equivalency. The LVS unit 220 recognizes the drawn shapes of the layout 210 that represent the electrical components of the circuit, as well as the connections between them. The derived electrical components are compared to the schematic netlist 200 to identify errors. The schematic netlist 200 includes basic dimensions for the components, such as width and length, for comparison to the layout file 210. The LVS unit 220 augments the schematic file by modifying the base entries to generate a layout netlist 230 that includes more detailed measurements, such as drain and source areas and perimeters.

The layout netlist 230 is provided to a memory array modeling unit 240. As will be described in greater detail below, the memory array modeling unit 240 generates one or more modified netlists 250 that replace memory arrays in the layout netlist 230 with a plurality of device primitives. These device primitives allow subsequent test pattern analysis units, such as an ATPG unit 260 and/or a fault grading unit 270 to analyze the modified netlist 250 including the memory arrays. In some embodiments, the memory array modeling unit 240 may be configured to automatically generate the memory array models according to preconfigured rules. In some embodiments, the memory array modeling unit 240 may allow a designer to manually create or edit the memory array models to specify the device primitives. For example, the memory array modeling unit 240 may identify memory arrays in the layout netlist 230 for the user to define.

As will be described in greater detail below, the modified netlist 250 may include an ATPG netlist 250A and/or a fault grading netlist 250B. The device primitives used for the modeling of the memory arrays may differ for the different types of test pattern analysis techniques. In addition, the fault grading unit 270 may use ATPG results 280 generated by the ATPG unit 260 to perform the fault grading analysis. For example, the ATPG unit 260 may use the ATPG netlist 250A to generate the ATPG results 280, which include a plurality of test patterns that are to be used to test the integrated circuit device. The fault grading unit 270 may then use the fault grading netlist 250B and the ATPG results 280 to perform the fault grading analysis.

Conventional test pattern analysis units bypass the memory arrays and rely on MBIST circuitry to test their functionality. The construct and operation of the ATPG unit and the fault grading unit 260, 270 are known to those of ordinary skill in the art, so they are not described in detail herein, other than to illustrate how the present subject matter deviates from the conventional approach. These units may be implanted in an integrated fashion in the application 165, or they may represent separate software components in a distributed system. The ATPG unit 260 may be implemented using FastScan™ software offered by Mentor Graphics of Wilsonville, Oreg. The fault grading unit 270 may be implemented using TetraMAX® software offered by Synopsys of Mountain View, Calif.

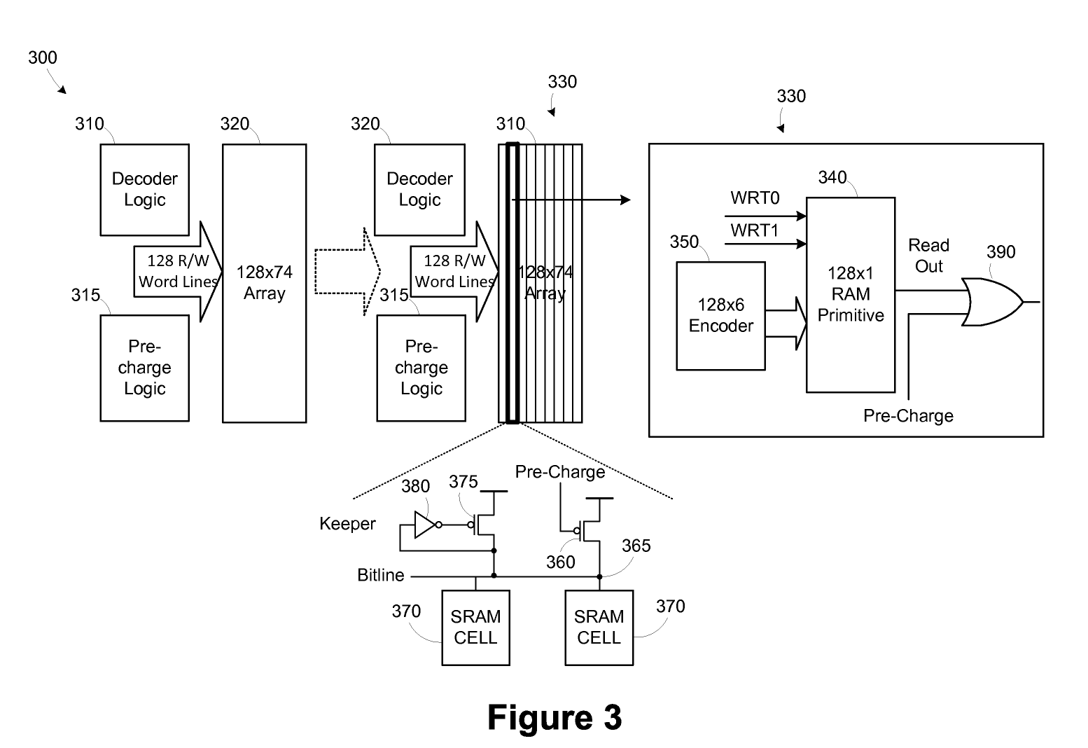

FIG. 3 illustrates a device 300, according to some embodiments. The device 300 includes decoder logic 310, pre-charge logic 315, and a memory array 320. The memory array 320 is a 128×74 bit array that allows a single read or write to a column at a given time (i.e., read and write are one hot). For the ATPG netlist 250A, the memory array modeling unit 240 models the device 300 by representing the memory array as a plurality of columns 330. Each column 330 is represented in the ATPG netlist 250A by a 128×1 RAM primitive 340 and the decoder logic 310 for each column is represented by a plurality of 128×6 encoders 350.

An SRAM typically has a pre-charge circuit for establishing initial bitline values prior to a read, and a keeper circuit to maintain the bit lines at a known value when the bit lines are floating (i.e., pre-charge is low). The pre-charge logic 315 sends a pre-charge signal to a pre-charge transistor 360, which charges a bit-line 365 for the SRAM cells 370. A keeper transistor 375 uses feedback from the bitline 365 through an inverter 380 to keep the bitline 365 at a charged state after the pre-charge signal is removed. In some embodiments, multiple bitlines 365 may be present and the pre-charge circuit may provide pre-charging and keeping functions for the multiple bitlines 365.

The pre-charge output is logically ORed via OR gate 390 with the output read data. When the pre-charge value is low, the output read data will go to the output of the memory, and when the pre-charge value is high, the output of the memory will be at the pre-charge or keeper value regardless of the output read data. This arrangement allows testing of the pre-charge and keeper devices 360, 375.

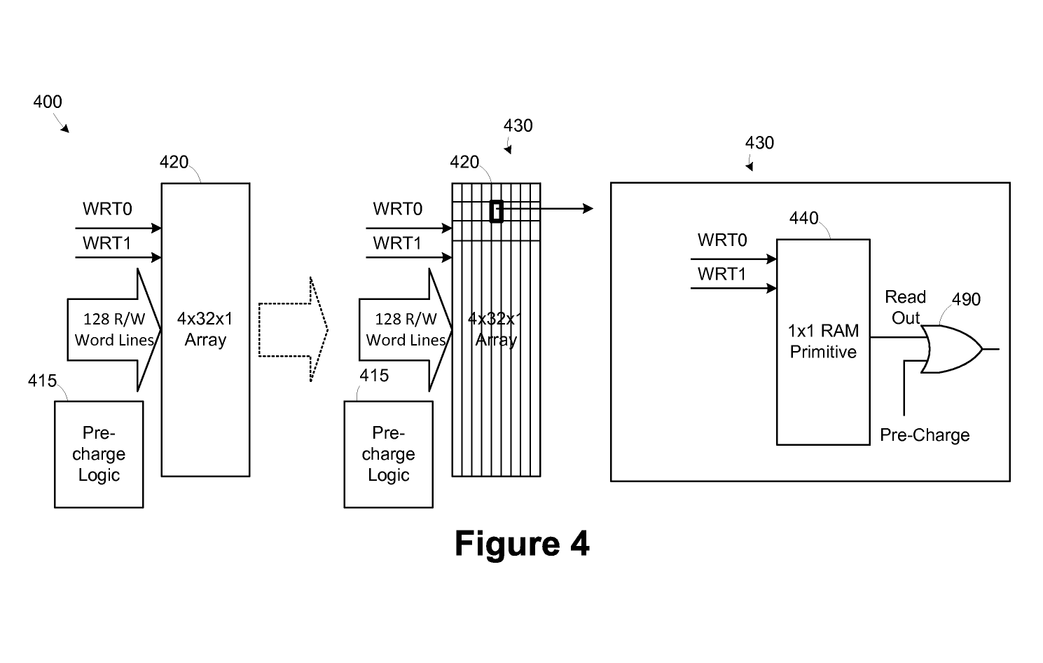

FIG. 4 illustrates a device 400 including pre-charge logic 415 and a memory array 420, according to some embodiments. The memory array 420 is a 4×32×1 array that is not one hot for reads and writes. For the ATPG netlist 250A, the memory array modeling unit 240 models the memory array 420 as a plurality of bit cells 430. Each bit cell 430 is represented by a bit cell primitive 440. The pre-charge and keeper modeling for the memory array 420 are handled in the same manner as described for FIG. 4 using the OR gate 490.

Modeling the devices 300, 400 for ATPG analysis as described above allows ATPG test patterns to target static and transition faults in the glue logic controlling the memory arrays 320, 420. ATPG path delay patterns may also be generated to target timing critical paths going through the memory array 320, 420.

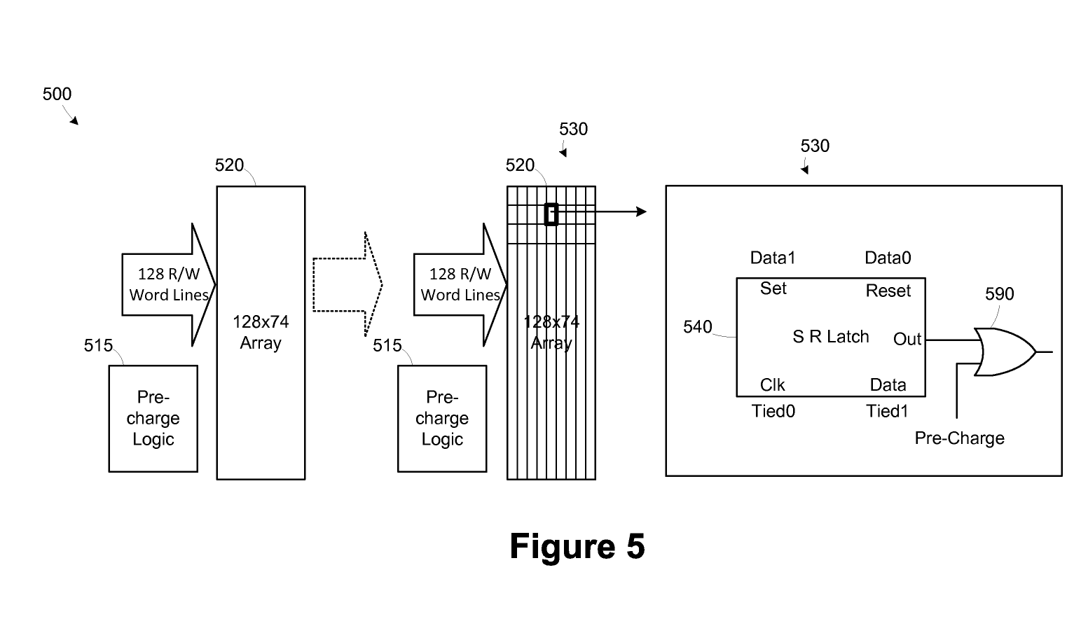

FIG. 5 illustrates a device 500 including pre-charge logic 515 and a memory array 520, according to some embodiments. The memory array 520 is a 128×74 array that is one hot for reads and writes. For the fault grading netlist 250B, the memory array modeling unit 240 models the memory array 520 as a plurality of latches 530. Each latch 530 is represented by a latch primitive 540. The use of the latch primitive 540 allows the targeting of glue logic faults and is also useful for MBIST fault grading. The pre-charge and keeper logic 515 for the memory array 520 are handled in the same manner as described for FIG. 4 using the OR gate 590. The use of the latch primitive 540 also allows of clock and data design rule check (DRC) issues to be avoided. The true data and the inverted data come to the bit cells of the memory array 520 from the same clock. A conventional ATPG analysis reports a DRC warning as it sees clock and data changing at the same time and does not proceed. By using the latch primitive 540 with true data going to the set port and the inverted data going to the reset port the ATPG unit 260 proceeds without a DRC error.

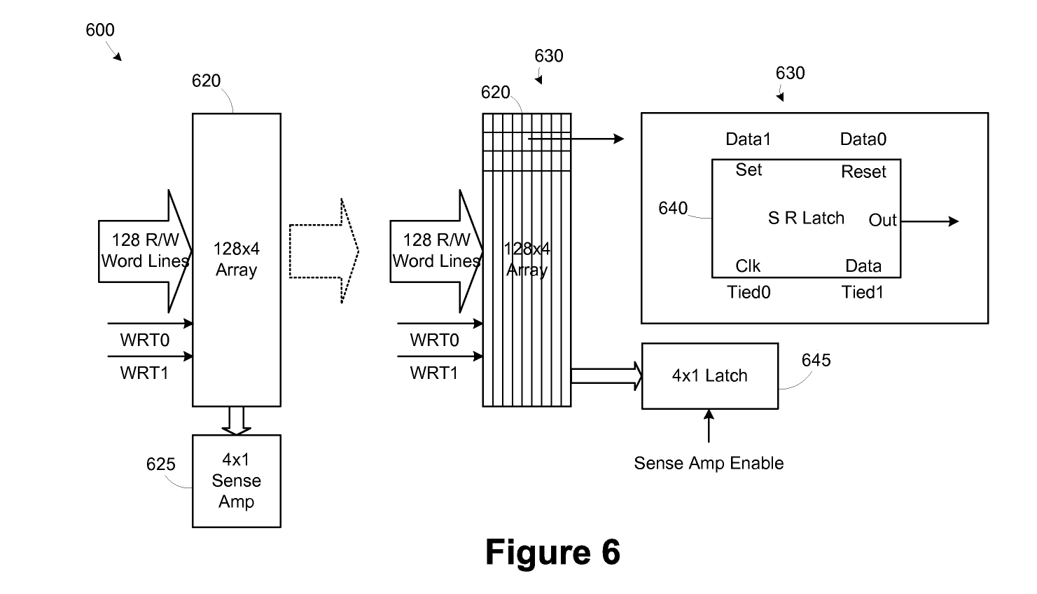

FIG. 6 illustrates a device 600 including a memory array 620 with a sense amp 625, according to some embodiments. The memory array 620 is a 128×4 array and the sense amp 625 is a 4×1 sense amp. For the fault grading netlist 250B, the memory array modeling unit 240 models the memory array 620 as a plurality of latches 630. Each latch 630 is represented by a latch primitive 640, and the sense amp 625 is modeled as a 4×1 latch primitive 645. In the embodiment of FIG. 6, the pre-charge and keeper logic is not modeled.

Using the ATPG netlist 250A and/or a fault grading netlist 250B to model the memory arrays increases the level of coverage available for the integrated circuit device over conventional MBIST testing for memory arrays. This increased coverage enhances the ability of a tester to identify faults therefore improves the reliability of the tested devices.

The particular embodiments disclosed above are illustrative only, as the subject matter may be modified and practiced in different but equivalent manners apparent to those skilled in the art having the benefit of the teachings herein. Furthermore, no limitations are intended to the details of construction or design herein shown, other than as described in the claims below. It is therefore evident that the particular embodiments disclosed above may be altered or modified and all such variations are considered within the scope and spirit of the subject matter. Accordingly, the protection sought herein is as set forth in the claims below.

1. A method, comprising:
receiving in a computing apparatus first and second models of an integrated circuit device including a memory array, wherein the memory array is modeled as a first plurality of device primitives in the first model and as a second plurality of device primitives in the second model, the second plurality of device primitives being different than the first plurality of device primitives;
performing a test pattern analysis of the memory array using the first model in the computing apparatus to generate a plurality of test patterns for testing the memory array based on the first plurality of device primitives; and
performing a fault grading analysis of the memory array using the second model and the plurality of test patterns in the computing device to determine fault coverage for the second model.

2. (canceled)

3. The method of claim 1, wherein the memory array comprises a plurality of bit cells and the first plurality of device primitives comprises a plurality of random access memory device primitives corresponding to the bit cells.

4. The method of claim 3, wherein the second model models the memory array as a plurality of latch device primitives corresponding to the bit cells.

5. (canceled)

6. The method of claim 1, wherein the memory array comprises a plurality of bit cells grouped into columns, and the first plurality of device primitives comprises a random access memory primitive for each column.

7. The method of claim 1, wherein the integrated circuit device comprises pre-charge logic operable to generate a pre-charge signal, the memory array includes at least one bit line coupled to at least one bit cell, an output terminal, and a pre-charge transistor coupled to the bit line and operable to receive the pre-charge signal, and the first model includes an OR gate having a first input coupled to the output terminal and a second input coupled to the pre-charge logic to receive the pre-charge signal.

8. The method of claim 1, wherein the memory array comprises a plurality of bit cells, and the first plurality of device primitives comprises a plurality of bit cell primitives.

9. (canceled)

10. The method of claim 1, wherein the integrated circuit device comprises a sense amp, the second model includes a latch representing the sense amp, and performing the fault grading analysis comprises performing the fault grading analysis of the memory array using at least one test pattern for testing the sense amp.

11. A system, comprising:
a memory array modeling unit to generate a first and second models of an integrated circuit device including a memory array, wherein the memory array is modeled as a first plurality of device primitives in the first model and as a second plurality of device primitives in the second model, the second plurality of device primitives being different than the first plurality of device primitives;
an automated test pattern generation unit to perform a test pattern analysis of the memory array using the model to generate a plurality of test patterns for testing the memory array based on the first plurality of device primitives; and
a fault grading unit to perform a fault grading analysis of the memory array using the second model and the plurality of test patterns to determine fault coverage for the second model.

12. (canceled)

13. The system of claim 11, wherein the memory array comprises a plurality of bit cells and the first plurality of device primitives comprises a plurality of random access memory device primitives and the second plurality of device primitives comprises a plurality of latch device primitives corresponding to the bit cells.

14. (canceled)

15. The system of claim 11, wherein the memory array comprises a plurality of bit cells grouped into columns, and the first plurality of device primitives comprises a random access memory primitive for each column.

16. The system of claim 11, wherein the integrated circuit device comprises pre-charge logic operable to generate a pre-charge signal, the memory array includes at least one bit line coupled to at least one bit cell, an output terminal, and a pre-charge transistor coupled to the bit line and operable to receive the precharge signal, the first model includes an OR gate having a first input coupled to the output terminal and a second input coupled to the pre-charge logic to receive the pre-charge signal.

17. The system of claim 11, wherein the memory array comprises a plurality of bit cells, and the first plurality of device primitives a plurality of bit cell primitives.

18. (canceled)

19. The system of claim 11, wherein the integrated circuit device comprises a sense amp, the second model includes a latch representing the sense amp, and the fault grading unit is operable to perform the fault grading analysis of the memory array using at least one test pattern for testing the sense amp.

20. A non-transitory program storage device programmed with instructions, that, when executed by a computing apparatus, perform a method comprising:
receiving first and second models of an integrated circuit device including a memory array, wherein the memory array is modeled as a first plurality of device primitives in the first model and as a second plurality of device primitives in the second model, the second plurality of device primitives being different than the first plurality of device primitives;
performing a test pattern analysis of the memory array using the first model to generate a plurality of test patterns for testing the memory array based on the first plurality of device primitives; and
performing a fault grading analysis of the memory array using the second model and the plurality of test patterns in the computing device to determine fault coverage for the second model.

21. (canceled)

22. The program storage device of claim 20, wherein the memory array comprises a plurality of bit cells, the first plurality of device primitive comprises a plurality of random access memory device primitives, and the second model models the memory array as a plurality of latch device primitives corresponding to the bit cells.
